(19) United States
(12) Patent Application Publication
(10) Pub. No.: US 2013/0338951 A1
(43) Pub. Date: Dec. 19, 2013

(54) ELECTRONIC SYSTEM WITH EMBEDDED SENSORS, METHOD FOR ESTIMATING AN OPERATING PHYSICAL QUANTITY, AND CORRESPONDING COMPUTER PROGRAM

(71) Applicants: Commissariat a I'energie atomique et aux ene alt, Paris (FR); Universite Montpellier 2 Sciences et Techniques, Montpellier (FR); Centre National de la Recherche Scientifique, Paris (FR)

(72) Inventors: Suzanne LESECQ, Froges (FR); Edith BEIGNE, Meaudre (FR); Philippe MAURINE, Quissac (FR); Lionel VINCENT, Fontaine (FR)

(73) Assignees: Commissariat a I'energie atomique et aux ene alt, Paris (FR); Universite Montpellier 2 Sciences et Techniques, Montpellier (FR); Centre National de la Recherche Scientifique, Paris (FR)

(21) Appl. No.: 13/897,743

(22) Filed: May 20, 2013

(30) Foreign Application Priority Data
May 24, 2012 (FR) 12 54781

(51) Int. Cl. G01R 19/25

(52) U.S. Cl. CPC G01R 19/25
USPC 702/64

(57) ABSTRACT

A system comprising: an electronic circuit exhibiting, in operation, a value v̅ of an operating physical quantity; a measurement device comprising: sensors embedded in the electronic circuit so as to provide raw measurements {Xₘ} sensitive to the value v̅ of the operating physical quantity, and an output unit for providing useful measurements {X′ₙ} on the basis of the raw measurements {Xₘ}; a distribution calculation device for determining a current distribution function F(x) associated with the useful measurements {X′ₙ}; a memory wherein associations {Aₖ} are saved, each association Aₖ associating a model distribution function Fₖ(x) with a model value v*ₖ of the operating physical quantity; and an estimation calculation device for determining an estimation \tilde{v} of the value v̅ of the operating physical quantity on the basis of the current distribution function F(x) and at least a portion of the saved associations {Aₖ}.

The present invention relates to an electronic system with embedded sensors, a method for estimating an operating physical quantity value and a corresponding computer program.

### BACKGROUND OF THE INVENTION

The invention is particularly applicable to the field of integrated circuits.

### DESCRIPTION OF THE PRIOR ART

The publication entitled “A fully integrated 32 nm Multiprobe for dynamic PVT measurements with complex digital SoC”, by L. Vincent, E. Beigne, L. Alacoque, S. Lesecq, C. Bour, Ph. Maurine, published in 2011 in “2nd European Workshop on CMOS Process Tuning and Variability, Vari 2011” describes an electronic system with embedded sensors, comprising:
an electronic circuit exhibiting, in operation, a value of an operating physical quantity, and
a measurement device comprising:
   sensors embedded in the electronic circuit so as to provide raw measurements sensitive to said value of the operating physical quantity, and
   an output unit for providing useful measurements on the basis of the raw measurements.

In this publication, the output unit does not carry out any particular processing such that the useful measurements are equal to the raw measurements, and are in the form of frequencies, sensitive to the temperature of the sensors, the power supply voltage of the sensors and the sensor production process. These three operating variables thus constitute the operating physical quantity mentioned above.

Each frequency is dependent on these three operating variables so that the precise value of each of these operating variables is not directly accessible on the basis of the frequencies. This means that the raw measurements do not provide direct information on the value of the operating physical quantity.

It may thus be sought to provide an electronic system with embedded sensors, for example such as in the above publication or any other type, for estimating the value of the operating physical quantity on the basis of the useful measurements.

### SUMMARY OF THE INVENTION

Therefore, the invention relates to an electronic system with embedded sensors, comprising:
an electronic circuit exhibiting, in operation, a value v̅ of an operating physical quantity,
a measurement device comprising:
   sensors embedded in the electronic circuit so as to provide raw measurements {Xₘ} sensitive to the value v̅ of the operating physical quantity, and
   an output unit for providing useful measurements {X′ₙ} on the basis of the raw measurements {Xₘ},
      further comprising:
a distribution calculation device for determining a current distribution function F(x) associated with the useful measurements {X′ₙ},
a memory wherein associations {Aₖ} are saved, each association Aₖ associating a model distribution function Fₖ(x) with a model value v*ₖ of the operating physical quantity,
an estimation calculation device for determining an estimation \tilde{v} of the value v̅ of the operating physical quantity on the basis of the current distribution function F(x) and at least a portion of the saved associations {Aₖ}.

In this way, the estimation \tilde{v} can be determined reliably, i.e. the estimation \tilde{v} obtained is close to the value v̅.

Optionally, the output unit is suitable for combining the raw measurements {Xₘ} to calculate the useful measurements {X′ₙ}, by adding the raw measurements {Xₘ} in pairs such that each useful measurement {X′ₙ} is the sum of two raw measurements {Xₘ}.

Also optionally, the estimation device comprises:
a preliminary selection unit for selecting model distribution functions {Fₖ₁(x)} in the memory,
a hypothesis testing unit for determining, for each previously selected model distribution function Fₖ₁(x), a distinctive value Cₖ₁, and for performing a hypothesis test using the distinctive values {Cₖ₁} to statistically select, from the previously selected model distribution functions {Fₖ₁(x)}, model distribution functions {Fₖ₂(x)},
an estimation calculation unit for determining the estimation \tilde{v} on the basis of the model values {v*ₖ₂} associated with the statistically selected model distribution functions {Fₖ₂(x)} and the corresponding distinctive values {Cₖ₂}.

Also optionally, the preliminary selection unit is suitable for selecting the previously selected model distribution functions {Fₖ₁(x)} according to an intermediate estimation \tilde{v}′ of the value v̅ of the operating physical quantity, in a predetermined manner in the event of absence of an intermediate estimation, and the estimation calculation unit is suitable for determining the intermediate estimation \tilde{v}′ on the basis of the values {v*ₖ₂} associated with the statistically selected model distribution functions {Fₖ₂(x)} and the corresponding distinctive values {Cₖ₂}, and, according to the result of a stop test, either providing the intermediate estimation \tilde{v}′ to the preliminary selection unit so as to form a recursive successive intermediate estimation determination loop, or providing the latest intermediate estimation \tilde{v}′ determined as the estimation \tilde{v}.

Also optionally, the hypothesis testing unit comprises:
a distinctive value calculation unit for determining, for each previously selected model distribution function Fₖ₁(x), a discriminant value tₖ₁ of a predetermined discriminant function Tₖ₁(F) dependent on the current distribution function F(x) and the previously selected model distribution function Fₖ(x), and for determining the distinctive value Cₖ₁ on the basis of the discriminant value tₖ₁, and
a statistical selection unit for selecting, from the previously selected model distribution functions {Fₖ₁(x)}, the statistically selected model distribution functions {Fₖ₂(x)} on the basis of the distinctive values {Cₖ₁}.

Also optionally, the distinctive value calculation unit is suitable for determining, for each discriminant value tₖ₁, the critical probability pcₖ₁ associated with discriminant value tₖ₁, and wherein the distinctive value Cₖ₁ is the critical probability pcₖ₁.

Also optionally, the statistical selection unit is suitable for selecting, from the previously selected distribution functions {Fₖ₁(x)}, those for which the distinctive value Cₖ₁ is greater than a threshold α.

Also optionally, the threshold α is equal to a predetermined percentage of the greatest of the distinctive values {Cₖ₁}.

The invention also relates to a method for estimating an operating physical quantity value, comprising:
receiving useful measurements {X′ₙ} from a measurement device comprising embedded sensors in an electronic circuit so as to provide raw measurements {Xₘ} sensitive to a value v̅ of an operating physical quantity exhibited by the electronic circuit in operation, wherein the useful measurements {X′ₙ} are determined on the basis of the raw measurements {Xₘ},
determining a current distribution function F(x) associated with the useful measurements {X′ₙ},
determining an estimation \tilde{v} of the value v̅ of the operating physical quantity on the basis of the current distribution function F(x) and at least a portion of associations {Aₖ} saved in a memory, wherein each association Aₖ associates a model distribution function Fₖ(x) with a model value v*ₖ of the operating physical quantity.

The invention also relates to a computer program downloadable from a communication network and/or saved on a computer-readable medium and/or executable by a processor, comprising instructions for executing the steps of a method according to the invention when said program is executed on a computer.

### BRIEF DESCRIPTION OF THE DRAWINGS

The invention will be understood more clearly using the description hereinafter, given merely as an example with reference to the appended figures wherein:

FIG. 1 schematically represents the general structure of a first electronic system with embedded sensors according to the invention,

FIG. 2 illustrates the successive steps of a method for operating the electronic system with embedded sensors in FIG. 1,

FIG. 3 schematically represents the general structure of a second electronic system with embedded sensors according to the invention, and

FIG. 4 illustrates the successive steps of a method for operating the electronic system with embedded sensors in FIG. 3.

### DESCRIPTION OF PREFERRED EMBODIMENTS

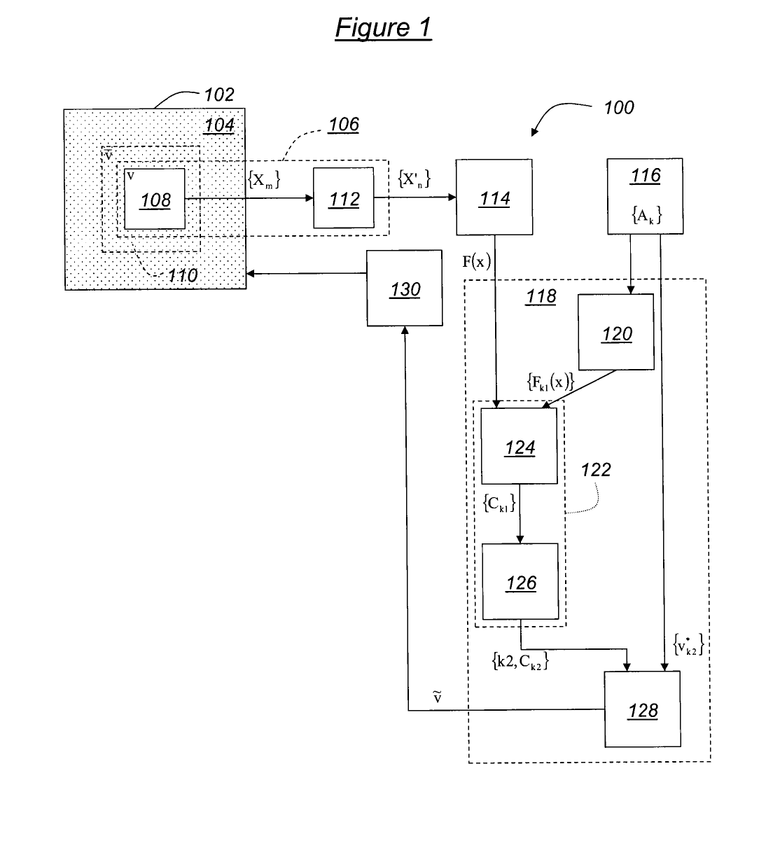

With reference to FIG. 1, a first electronic system 100 with embedded sensors will be described.

The electronic system with embedded sensors 100 firstly comprises a chip 102 whereon components are embedded to form an electronic circuit 104 (shown as a dotted line in FIG. 1) for performing one or a plurality of predetermined functions. The chip 102 consists of a semi-conductor wafer whereon the components of the electronic circuit 104 are etched or printed.

The electronic system with embedded sensors 100 further comprises a measurement device 106.

The measurement device 106 firstly comprises sensors 108 embedded in the chip 102 so as to monitor the operation of a zone 110 of the electronic circuit 104 around the sensors 108. The sensors 108 are thus also printed on the semi-conductor wafer forming the chip 102. However, the sensors 108 are not involved in performing the predetermined function(s) of the electronic circuit 104.

More specifically, during the operation of the electronic circuit 104, the monitored zone 110 exhibits a value v̅ of an operating physical quantity, and the sensors 108 are intended to monitor this value v̅.

A physical quantity is any property or set of properties suitable for being quantified by measurement or calculation, and for which the various possible values can be expressed for example using a number, which is real or complex for example, generally accompanied by a measurement unit.

The sensors 108 are suitable for being sensitive to the same operating physical quantity as the monitoring zone 110, i.e. a physical quantity of the same kind. Ideally, during the operation thereof, the sensors 108 exhibit the same value v̅ as the monitored zone 110. However, in practice, they may exhibit a different value v to the value v̅, but nonetheless close to the value v̅, or at least exhibiting the same variations as the value v̅.

In this way, the sensors 108 are suitable for providing, whenever they are queried, M measurements, referred to as raw measurements {Xₘ} (m=1 . . . M), dependent on the value v of the operating physical quantity. For example, each sensor provides one of the raw measurements {Xₘ}, such that there are the same number of sensors 106 and raw measurements {Xₘ}.

As explained above, since the value v is substantially equal to the value v̅, or at least exhibits the same sensitivities and/or variations, the raw measurements {Xₘ} are thus sensitive to the value v̅ of the operating physical quantity of the monitored zone 110.

In the example described, the operating physical quantity is two-dimensional: it includes the temperature and the power supply voltage. In this way, the value v̅ consists of the temperature value T̅ of the monitored zone 110 and the power supply voltage value V̅ of the monitored zone, i.e.: v̅=( T̅, V̅), whereas the value v consists of the temperature value T of the sensors 108 and the power supply voltage value V of the sensors 108, i.e. v=(T,V).

In the example described, the embedding of the sensors 108 means that the sensors 108 are printed on the same chip 102 as the electronic circuit 104, particularly using the same printing process. This further means that the sensors 108 are powered by the same power supply, supplying the power supply voltage, as the electronic circuit 104 and particularly as the monitored zone 110.

In the example described, the sensors 108 are all of the same type and thus produce the same type of raw measurement. However, the behaviour of each sensor (i.e. the raw measurement provided) subject to the same variations of the operating physical quantity as the other sensors is preferably as different as possible to that of the other sensors. In this way, the data provided by the sensors 108 are not redundant.

For example, the device referred to as a “Multiprobe” described in the publication entitled “A Fully Integrated 32 nm MultiProbe for Dynamic PVT Measurements within Complex Digital SoC” by L. Vincent, E. Beigné, L. Alocoque, S. Lesecq, C. Bour and P. Maurine, and published in “2nd European Workshop on CMOS Variability”, VARI 2011, 2011, is used to form sensors 108. As described in this publication, each sensor 108 is a ring oscillator wherein the oscillation frequency is sensitive to the temperature value thereof and the power supply voltage value thereof. Such a ring oscillator provides, as the raw measurement, an oscillation frequency measurement.

The measurement device 106 further comprises an output unit 112 for determining N measurements, referred to as useful measurements {X′ₙ} (n=1 . . . N), on the basis of the raw measurements {Xₘ}.

Preferably, the useful measurements {X′ₙ} are greater in number than the raw measurements {Xₘ}. Indeed, this makes it possible to increase the power of the statistical test to be carried out with the features described hereinafter, i.e. increases the probability of rejecting the null hypothesis of this statistical test.

In the example described, the output unit 112 is suitable for combining the raw measurements {Xₘ} to calculate the useful measurements {X′ₙ}. For example, the output unit 112 is suitable for adding the raw measurements {Xₘ} in pairs such that each useful measurement {X′ₙ} is the sum of two raw measurements {Xₘ}. Alternatively, the output unit 112 may be suitable for calculating the difference of pairs of raw measurements {Xₘ} such that each useful measurement {X′ₙ} is the difference of two of the raw measurements {Xₘ}. During studies conducted, it was found that the sum of the raw measurements in pairs gave superior results to the difference of pairs. Also alternatively, the output unit 112 may be suitable for calculating the difference of three raw measurements {Xₘ}, or any other type of possible combination.

The electronic system with embedded sensors 100 further comprises a distribution calculation device 114 for determining a distribution function, referred to as the current distribution function F(x), associated with the useful measurements {X′ₙ}.

In the example described, the current distribution function F(x) represents the proportion of the useful measurements {X′ₙ} wherein the value is less than or equal to x, and is given by:

$$F ( x ) = \frac{1}{N} {\sum }_{n = 1}^{N} {1}_{] - ∞ , x ]} ( {X}_{n}^{′} ) ,$$

where 1_{]-∞,x]} is a function equal to 1 when X′ₙ is within ]−∞,x] and 0 otherwise.

In this way, the current distribution function F(x) is an incremental function and the number of increments is equal to the number N of useful measurements {X′ₙ}.

The electronic system with embedded sensors 100 further comprises a memory 116 wherein K associations, referred to as available associations {Aₖ} (where k=1 . . . K), are saved. Each available association Aₖ associates an available model distribution function Fₖ(x) with an available model value v*ₖ of the operating physical quantity. The available associations {Aₖ} are for example saved in the form of a Look-Up Table (LUT). Each available model distribution function Fₖ(x) and associated available model value v*ₖ is for example obtained by means of a simulation of the electronic circuit 104 and the sensors 108, and/or by a characterisation of the sensors 108, and/or by calibrating the sensors 108.

The available model values {v*ₖ} thus form a spatial block of possible values. In one embodiment, the block is regular. In the example described, this means that the difference between model temperature and voltage values is always the same. In another embodiment, the block is irregular. In the example described, this means that two model temperature and voltage values vary according to the two model values in question. In particular, this difference may be more confined for the spatial zones of the most indecisive possible values. In a further embodiment, the block is staggered, limiting the number of available model values while minimising the distance between these values.

In the example described, each available model distribution function Fₖ(x) is obtained by taking into consideration model useful measurement values, obtained empirically on a test electronic system with embedded sensors and/or by modeling and calculations. In this way, the available model distribution function Fₖ(x) is also an incremental function, wherein the number of increments, referenced Mₖ, is equal to the number of model useful measurements.

In one particular embodiment, all the available model distribution functions Fₖ(x) have the same number of increments, for example equal to the number N of useful measurements {X′ₙ}.

The electronic system with embedded sensors 100 further comprises an estimation device 118 for determining an estimation \tilde{v} of the value v of the operating physical quantity, and thus also of the value \tilde{v} of the operating physical quantity, on the basis of the current distribution function F(x) and at least a portion of the available associations {Aₖ} saved in the memory 116.

In the example described, the estimation device 118 firstly comprises a preliminary selection unit 120 for selecting in the memory 116, from the available model distribution functions {Fₖ(x)}, model distribution functions, referred to as previously selected model distribution functions {Fₖ₁(x)} (where k1 ∈ [1,K]). In the example in FIG. 1, the preliminary selection unit 120 is suitable for selecting all the available model distribution functions {Fₖ(x)}.

In the example described, the estimation device 118 further comprises a hypothesis testing unit 122 for performing a hypothesis test in order to statistically select, from the previously selected model distribution functions {Fₖ₁(x)}, model distribution functions, referred to as statistically selected model distribution functions {Fₖ₂(x)} (where k2 ∈ [1,K]). For each previously selected model distribution function Fₖ₁(x), the hypothesis test has the following null hypothesis: “the current distribution function F(x) is equal to the distribution function Fₖ₁(x)”, and the following opposite hypothesis: “the current distribution function F(x) is not equal to the distribution function Fₖ₁(x)”. The hypothesis test is for example the Smirnov hypothesis test (modern variant or historic variant) or the Cramér-von Mises hypothesis test.

In the example described, the hypothesis testing unit 122 firstly comprises a distinctive value calculation unit 124 for determining, for each previously selected model distribution function Fₖ₁(x), a distinctive value Cₖ₁. The distinctive value Cₖ₁ represents a difference between the current distribution function F(x) and the previously selected model distribution function Fₖ₁(x).

In the example described, the distinctive value calculation unit 124 is suitable for determining, for each previously selected model distribution function Fₖ₁(x), a value, referred to as the discriminant value tₖ₁, of a predetermined function, referred to as the discriminant function Tₖ₁(F). The discriminant function Tₖ₁(F) is dependent on the current distribution function F(x) and the previously selected model distribution function Fₖ₁(X).

In the example described, the discriminant function Tₖ₁(F) is chosen such that the value tₖ₁ of Tₖ₁(F) tends to move away from 0 when the null hypothesis is not true (bilateral hypothesis test).

For example, in the case of the Smirnov hypothesis test, the discriminant function Tₖ₁(F) is based on the maximum deviation between the two distribution functions tested. In this way, the Smirnov hypothesis test is based on the observation of a single point of the tested distribution functions, i.e. that corresponding to the maximum distance between the distribution functions. The discriminant function Tₖ₁(F) is thus:

$${T}_{k 1} ( F ) \text{:} {t}_{k 1} = {sup}_{x} \vert {F}_{k 1} ( x ) - F ( x ) \vert .$$

In the case of the Cramér-von Mises test, the discriminant function Tₖ₁(F) measures the difference between the two distribution functions tested on the entire ranges thereof, thus offering a good alternative to the Smirnov hypothesis test. The discriminant function Tₖ₁(F) thus equals:

$${T}_{k 1} ( F ) \text{:} {t}_{k 1} = \frac{{NM}_{k 1}}{N + {M}_{k 1}} {\int }_{- ∞}^{+ ∞} {[ {F}_{k 1} ( x ) - F ( x ) ]}^{2} d F ( x ) .$$

In the example described, since the distribution functions are incremental functions, commonly referred to as empirical distribution functions, the discriminant function Tₖ₁(F) is calculated by:

$${T}_{k 1} ( F ) \text{:} {t}_{k 1} = \frac{U}{{NM}_{k 1} ( N + {M}_{k 1} )} - \frac{4 N {M}_{k 1} - 1}{6 ( {M}_{k 1} + N )} , \\ where \text{:}$$

$$U = N {\sum }_{i = 1}^{N} {( {r}_{i} - i )}^{2} + {M}_{k 1} {\sum }_{j = 1}^{{M}_{k 1}} {( {s}_{j} - j )}^{2} ,$$

where, the useful values being classified in increasing order in a first vector and the model useful values being classified in increasing order in a second vector, these two vectors being combined in a single vector, referred to as a combined vector, such that the values contained in the combined vector are also classified in increasing order, i is the rank of the useful values in the first vector and rᵢ is the rank of the useful values in the combined vector, and j is the rank of the model useful values in the second vector and sⱼ is the rank of these model useful values in the combined vector.

The distinctive value calculation unit 120 is further suitable for determining the distinctive value Cₖ₁ on the basis of the discriminant value tₖ₁.

In one embodiment, the distinctive value Cₖ₁ is the discriminant value tₖ₁. For example, this is the case of the historic Smirnov hypothesis test.

In a further embodiment, the distinctive value Cₖ₁ is a probability, referred to as the critical probability pcₖ₁, for obtaining a value of the discriminant function Tₖ₁(F) equal to the value tₖ₁ or more extreme (i.e. in the case of the bilateral hypothesis test, a value t such that |t|>|tₖ₁|).

For example, this is the case for the modern Smirnov hypothesis test (commonly referred to as the Kolmogorov-Smirnov test), where the critical probability pcₖ₁ equals:

$${pc}_{k 1} = 2 {\sum }_{j = 1}^{+ ∞} {( - 1 )}^{j + 1} {e}^{( - 2 {k}^{2} {j}^{2} )} , \\ where \text{:}$$

$$y = \sqrt{\frac{{NM}_{k 1}}{N + {M}_{k 1}}} {T}_{k 1} ( F ) .$$

In practice, as the sum on j converges very quickly to the infinity value thereof, only the first J terms of the sum are determined, such that pcₖ₁ is determined by:

$${pc}_{k 1} = 2 {\sum }_{j = 1}^{J} {( - 1 )}^{j + 1} {e}^{( - 2 {k}^{2} {j}^{2} )} .$$

For example, J is between 3 and 100, which is sufficient to suitably approximate the value at infinity.

In the case of the Cramér-von Mises hypothesis test, the distinctive value Cₖ₁ may also be the critical probability pcₖ₁. In this case, the critical probability pcₖ₁ equals:

$${pc}_{k 1} = \frac{{T}_{k 1} ( F ) - ɛ {T}_{k 1} ( F )}{\sqrt{45 \cdot Var ( {T}_{k 1} ( F ) )}} + \frac{1}{6}$$

$$where \text{:}$$

$$ɛ T = \frac{1}{6} + \frac{1}{6 ( {M}_{k 1} + N )} , \\ and \text{:}$$

$$Var ( {T}_{k 1} ( F ) ) = \frac{1}{45} \cdot \frac{{M}_{k 1} + N + 1}{{( {M}_{k 1} + N )}^{2}} \cdot \frac{4 {M}_{k 1} N ( {M}_{k 1} + N ) - 3 ( {M}_{k 1}^{2} + {N}^{2} ) - 2 {M}_{k 1} N}{4 {M}_{k 1} N} .$$

In the example described, the hypothesis testing unit 122 further comprises a statistical selection unit 126 for selecting, from the previously selected model distribution functions {Fₖ₁(x)}, on the basis of the distinctive values {Cₖ₁} thereof, model distribution functions, referred to as statistically selected model distribution functions {Fₖ₂(x)}. More specifically, the statistical selection unit 126 is suitable for comparing the distinctive value Cₖ₁ to a threshold in order to select, according to the comparison, the statistically selected model distribution functions {Fₖ₂(x)}.

In the example described, the statistical selection unit 126 is suitable for providing identifiers of the statistically selected model distribution functions {Fₖ₂(x)}, for example the indexes k2, and the corresponding distinctive values {Cₖ₂}.

If the distinctive value Cₖ₁ is the critical probability pcₖ₁, the statistical selection unit 126 is suitable for selecting the previously selected model distribution functions {Fₖ₁(x)} wherein the distinctive value Cₖ₁ is greater than a threshold α. Indeed, if the critical probability pcₖ₁ is less than the threshold α, this means that the null hypothesis is rejected.

In the example described, the threshold α is equal to a predetermined percentage of the greatest of the distinctive values {Cₖ₁}. Preferably, the predetermined percentage is greater than 50%. For example, the predetermined percentage is 90% or more, making it possible to only select the most probable model distribution functions. Indeed, it was found that the latter scenario gave superior results.

If the distinctive value Cₖ₁ is the discriminant value tₖ₁, in order to ensure that at least one model distribution function is selected and to reduce the memory size required by avoiding saving quantile tables, the threshold α is preferably defined as above as a predetermined percentage of the greatest of the distinctive values {Cₖ₁}.

In the example described, the estimation device 118 further comprises an estimation calculation unit 128 for determining the estimation \tilde{v} on the basis of the model values {v*ₖ₂} saved in the memory 116 and associated with the statistically selected model distribution functions {Fₖ₂(x)} and the corresponding distinctive values {Cₖ₂}. For example, the estimation \tilde{v} is equal to the mean of the selected values {v*ₖ₂} weighted with the corresponding distinctive values {Cₖ₂}.

In the embodiment described, the electronic system with embedded sensors 100 further comprises a control device 130 for controlling the operation of the electronic circuit 104 according to the estimation \tilde{v}. The aim of the control device 130 is for example that of optimally adjusting the performances of the electronic circuit 104 in a low electricity consumption context.

Moreover, in one embodiment, all or part of the distribution calculation device 114 and the estimation device 118 is implemented in the form of a computer program executed by a processing unit (not shown).

It should be noted that, as a general rule, all the features described above apart from the sensors 108, the memory 116 and the control device 130 may be implemented in the form of a computer program executed by a processing unit (not shown).

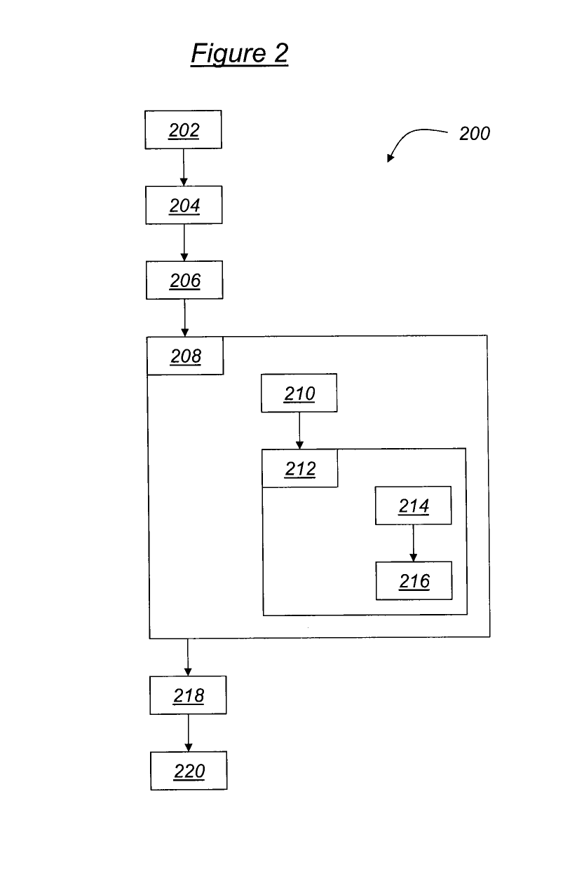

With reference to FIG. 2, a method 200 for operating the electronic system with embedded sensors 100 will be described.

During a step 202, the sensors 108 are queried and provide the raw measurements {Xₘ}.

During a step 204, the output unit 112 combines the raw measurements {Xₘ} to calculate the useful measurements {X′ₙ}.

During a step 206, the distribution calculation device 114 receives the useful measurements {X′ₙ} and determines the current distribution function F(x) associated with the useful measurements {X′ₙ}.

During a step 208, the estimation device 118 determines an estimation \tilde{v} of the value v of the operating physical quantity, and thus also of the value v̅ of the operating physical quantity, on the basis of the current distribution function F(x) and at least a portion of the available associations {Aₖ} saved in the memory 116. The step 208 comprises the following steps 210 to 216.

During a step 210, the preliminary selection unit 120 selects, in the memory 116, from the available model distribution functions {Fₖ(x)}, previously selected model distribution functions {Fₖ₁(x)}. In the example described, the selection is predetermined. For example, all the available model distribution functions {Fₖ(x)} are selected.

During a step 212, the hypothesis testing unit 122 performs a hypothesis test to select, from the previously selected model distribution functions {Fₖ₁(x)}, statistically selected model distribution functions {Fₖ₂(x)}. The step 212 comprises the following steps 214 and 216.

During a step 214, the distinctive value calculation unit 124 determines, for each previously selected model distribution function Fₖ₁(x), the corresponding distinctive value Cₖ₁. As explained above, according to the embodiment, this distinctive value Cₖ₁ is either the discriminant value tₖ₁, or the critical probability pcₖ₁ associated with the discriminant value tₖ₁.

During a step 216, the statistical selection unit 126 selects, from the previously selected model distribution functions {Fₖ₁(x)}, on the basis of the distinctive values {Cₖ₁} thereof, the statistically selected model distribution functions {Fₖ₂(x)}. The statistical selection unit further provides identifiers of the statistically selected model distribution functions {Fₖ₂(x)} and the corresponding distinctive values {Cₖ₂}.

During a step 218, the estimation calculation unit 128 determines the estimation \tilde{v} on the basis of the values {v*ₖ₂} obtained in the memory 116 by means of the identifiers, and the distinctive values {Cₖ₂}.

During a step 220, the control device 130 controls the operation of the electronic circuit 104 according to the estimation \tilde{v}.

The method then starts again at step 202 for a further estimation. The estimations are for example performed at regular time intervals.

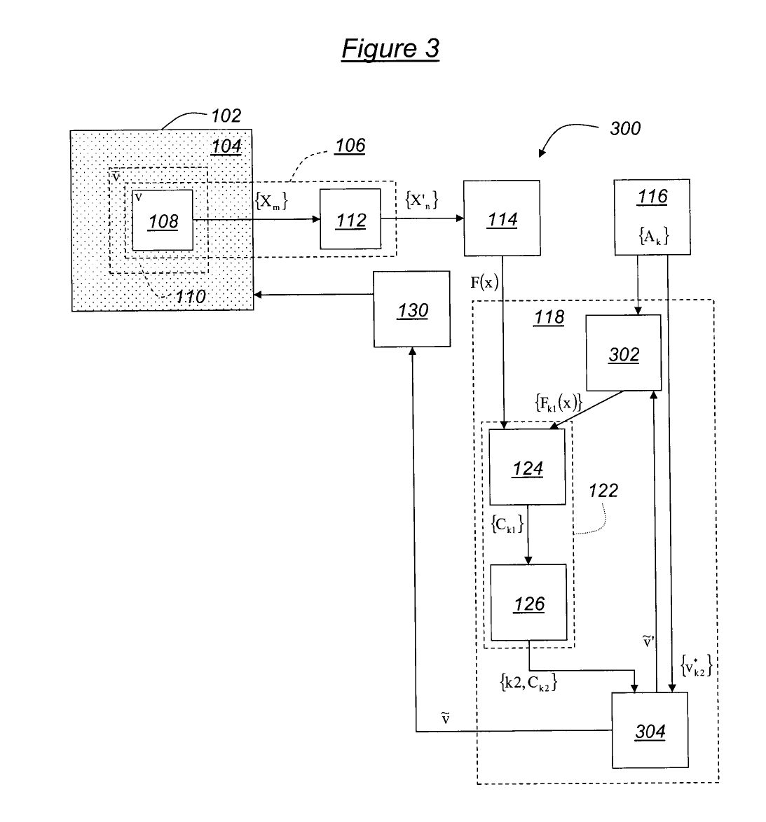

With reference to FIG. 3, a second electronic system 300 with embedded sensors will be described.

The electronic system with embedded sensors 300 is identical to that in FIG. 1, except that the preliminary selection unit, now bearing the reference 302, is suitable for selecting, from the available model distribution functions {Fₖ(x)} of the memory 116, the previously selected model distribution functions {Fₖ₁(x)} according to an intermediate estimation \tilde{v}′ of the value v of the operating physical quantity, and thus also of the value v̅ of the operating physical quantity, in a predetermined manner in the event of absence of an intermediate estimation.

For example, in the event of the absence of an intermediate estimation, the preliminary selection unit 302 is suitable for selecting model distribution functions wherein the associated model values form, in the example described, a regular spatial block of possible values. However, as mentioned above, the block may be irregular.

When an intermediate estimation \tilde{v}′ is available, the preliminary selection unit is for example suitable for selecting model distribution functions wherein the associated model values are situated around the intermediate estimation \tilde{v}′, for example at a distance less than or equal to a predetermined distance. Preferably, the model values associated with the selected model distribution functions are separated by decreasing distances for each further intermediate estimation \tilde{v}′. This makes it possible to recursively confine the block around the most probable value.

The preliminary selection unit 302 thus makes it possible to limit the calculations made and thus the cost in calculation time, while retaining satisfactory results. For example, it was found that the same precision as for the electronic system with embedded sensors in FIG. 1 is obtained with calculation savings of approximately 60%.

Furthermore, the estimation calculation unit, now bearing the reference 304, is suitable for determining the intermediate estimation \tilde{v}′ on the basis of the distinctive values {Cₖ₂} determined by the statistical selection unit 126. The intermediate estimation \tilde{v}′ is for example equal to the mean of the selected values {v*ₖ₂} weighted by the corresponding distinctive values {Cₖ₂}.

The estimation calculation unit 304 is further suitable for evaluating a stop test relating to the intermediate estimation and, according to the result of the stop test, either providing the intermediate estimation \tilde{v}′ to the preliminary selection unit 302 so as to form a recursive loop for determining intermediate estimations \tilde{v}′, or providing the latest intermediate estimation \tilde{v}′ determined as the estimation \tilde{v}.

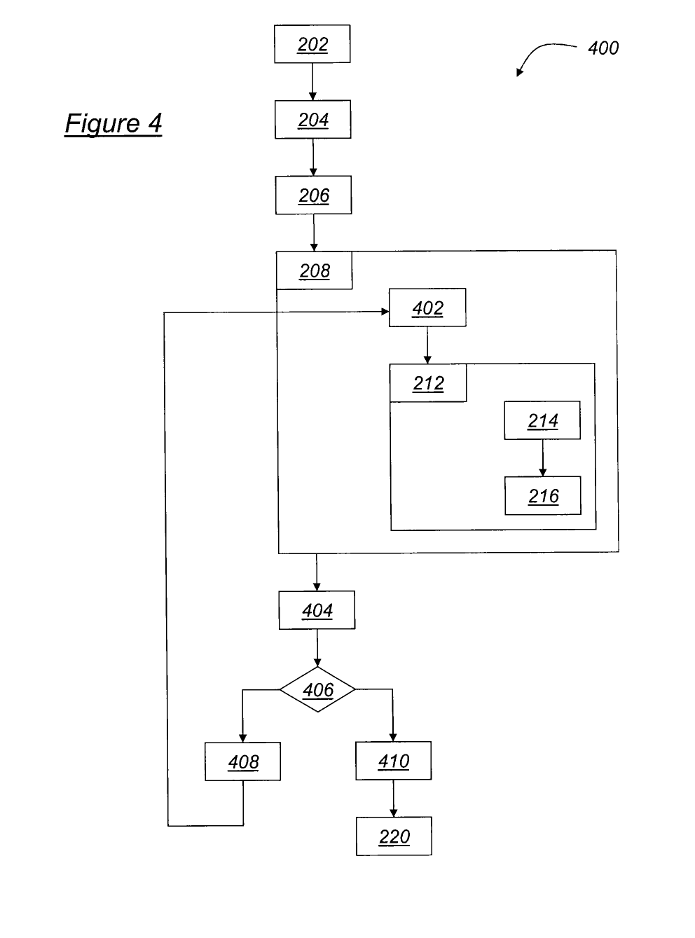

With reference to FIG. 4, a method 400 for operating the electronic system with embedded sensors 300 will be described.

The operating method 400 is identical to that in FIG. 2, except that the step 210 is replaced by a step 402 wherein the preliminary selection unit 302 selects, from the available model distribution functions {Fₖ(x)} of the memory 116, the previously selected model distribution functions {Fₖ₁(x)} according to an intermediate estimation \tilde{v}′ of the value v of the operating physical quantity, and thus also of the value \tilde{v} of the operating physical quantity, in a predetermined manner in the event of absence of an intermediate estimation.

Furthermore, the step 218 is replaced by the following steps 404 to 410.

During a step 404, the estimation calculation unit 304 determines the intermediate estimation \tilde{v}′ on the basis of the model values {v*ₖ₂} and the distinctive values {Cₖ₂}.

During a step 406, the estimation calculation unit 304 evaluates a stop test relating to the intermediate estimation \tilde{v}′.

During a step 408, if the result of the stop test is negative, the estimation calculation unit 304 supplies the intermediate estimation \tilde{v}′ to the preliminary selection unit 302 and the method 400 returns to the step 402 so as to form a recursive loop for determining successive intermediate estimations \tilde{v}′.

During a step 410, if the result of the stop test is positive, the estimation calculation unit 304 provides the latest intermediate estimation \tilde{v}′ determined as the estimation \tilde{v}.

It is clear that an electronic system with embedded sensors such as that described above is suitable for estimating the value of an operating physical quantity of a zone of an electronic circuit, and the progression of this value over time. The electronic system with embedded sensors is particularly suitable for monitoring a multidimensional physical quantity even though the sensors provide measurements of the same type.

Moreover, the invention is not limited to the embodiments described above. Indeed, it would be obvious for those skilled in the art that various modifications may be made to the embodiments described above, in the light of the teaching disclosed herein.

In particular, the operating physical quantity is not necessarily two-dimensional. In other embodiments, it could be one-dimensional or multidimensional with more than two dimensions.

Furthermore, the operating physical quantity could include, in addition to or instead of the temperature and power supply voltage, the electronic circuit product process. Indeed, electronic circuits produced using the same procedure may differ from each other, for example because different production runs of parts have been used. In this case, the different values characterising the production process may for example be expressed by a word describing the performances of the circuit in relation to the expected performances, and not by a figure.

Furthermore, the raw measurements are not necessarily combined. In this case, the output unit may be a mere wire and the useful measurements are thus equal to the raw measurements.

Furthermore, in one alternative embodiment, the statistical selection unit is suitable for determining whether the greatest of the distinctive values is less than a predetermined threshold or not. If the greatest of the distinctive values is less than the predetermined threshold, this means that no model distribution function is similar to the current distribution function, i.e. that it is unlikely that the useful measurements are obtained from any of the model distribution functions. In this case, the statistical selection unit is suitable for modifying the operation of one or a plurality of: the output unit, the preliminary selection unit, the distinctive value calculation unit and the statistical selection unit, and resuming the determination of the estimation (final or intermediate according to the embodiment) on the basis of the raw measurements. For example, the statistical selection unit may modify the type of combination used to obtain the useful measurements on the basis of the raw measurements, or the statistical selection unit may modify the manner in which the preliminary selection unit selects the available model distribution functions, or the statistical selection unit may modify the test used for calculating the distinctive value, or the statistical selection unit may modify the threshold used for selecting the statistically selected model distribution functions.

In the claims hereinafter, the terms used should not be interpreted as limiting the claims to the embodiments disclosed in the description, but should be interpreted to include any equivalents intended to be covered by the claims due to the wording thereof and which are foreseeable by those skilled in the art applying their general knowledge to the implementation of the teaching disclosed herein.

1. An electronic system with embedded sensors, comprising:
an electronic circuit exhibiting, in operation, a value v̅ of an operating physical quantity,
a measurement device comprising:
sensors embedded in the electronic circuit so as to provide raw measurements {Xₘ} sensitive to the value v̅ of the operating physical quantity,
an output unit for providing useful measurements {X′ₙ} on the basis of the raw measurements {Xₘ},
further comprising:
a distribution calculation device for determining a current distribution function F(x) associated with the useful measurements {X′ₙ},
a memory wherein associations {Aₖ} are saved, each association Aₖ associating a model distribution function Fₖ(x) with a model value v*ₖ of the operating physical quantity,
an estimation calculation device for determining an estimation \tilde{v} of the value v̅ of the operating physical quantity on the basis of the current distribution function F(x) and at least a portion of the saved associations {Aₖ}.

2. The electronic system with embedded sensors as claimed in claim 1, wherein the output unit is suitable for combining the raw measurements {Xₘ} to calculate the useful measurements {X′ₙ}, by adding the raw measurements {Xₘ} in pairs such that each useful measurement {X′ₙ} is the sum of two raw measurements {Xₘ}.

3. The electronic system with embedded sensors as claimed in claim 1, wherein the estimation device comprises:
a preliminary selection unit for selecting model distribution functions {Fₖ₁(x)} in the memory,
a hypothesis testing unit for determining, for each previously selected model distribution function Fₖ₁(x), a distinctive value Cₖ₁, and for performing a hypothesis test using the distinctive values {Cₖ₁} to statistically select, from the previously selected model distribution functions {Fₖ₁(x)}, model distribution functions {Fₖ₂(x)},
an estimation calculation unit for determining the estimation \tilde{v} on the basis of the model values {v*ₖ₂} associated with the statistically selected model distribution functions {Fₖ₂(x)} and the corresponding distinctive values {Cₖ₂}.

4. The electronic system with embedded sensors as claimed in claim 3, wherein:
the preliminary selection unit is suitable for selecting the previously selected model distribution functions {Fₖ₁(x)} according to an intermediate estimation \tilde{v}′ of the value v̅ of the operating physical quantity, in a predetermined manner in the event of absence of an intermediate estimation, and
the estimation calculation unit is suitable for determining the intermediate estimation \tilde{v}′ on the basis of the values {v*ₖ₂} associated with the statistically selected model distribution functions {Fₖ₂(x)} and the corresponding distinctive values {Cₖ₂}, and, according to the result of a stop test, either providing the intermediate estimation \tilde{v}′ to the preliminary selection unit so as to form a recursive successive intermediate estimation determination loop, or providing the latest intermediate estimation \tilde{v}′ determined as the estimation \tilde{v}.

5. The electronic system with embedded sensors as claimed in claim 3, wherein the hypothesis testing unit comprises:
a distinctive value calculation unit for determining, for each previously selected model distribution function Fₖ₁(x), a discriminant value tₖ₁ of a predetermined discriminant function Tₖ₁(F) dependent on the current distribution function F(x) and the previously selected model distribution function Fₖ(X), and for determining the distinctive value Cₖ₁ on the basis of the discriminant value tₖ₁, and
a statistical selection unit for selecting, from the previously selected model distribution functions {Fₖ₁(x)}, the statistically selected model distribution functions {Fₖ₂(x)} on the basis of the distinctive values {Cₖ₁}.

6. The electronic system with embedded sensors as claimed in claim 5, wherein the distinctive value calculation unit is suitable for determining, for each discriminant value tₖ₁, the critical probability pcₖ₁ associated with discriminant value tₖ₁, and wherein the distinctive value Cₖ₁ is the critical probability pcₖ₁.

7. The electronic system with embedded sensors as claimed in claim 5, wherein the statistical selection unit is suitable for selecting, from the previously selected distribution functions {Fₖ₁(x)}, those for which the distinctive value Cₖ₁ is greater than a threshold α.

8. The electronic system with embedded sensors as claimed in claim 7, wherein the threshold α is equal to a predetermined percentage of the greatest of the distinctive values {Cₖ₁}.

9. A method for estimating an operating physical quantity value, comprising:
receiving useful measurements {X′ₙ} from a measurement device comprising embedded sensors in an electronic circuit so as to provide raw measurements {Xₘ} sensitive to a value v̅ of an operating physical quantity exhibited by the electronic circuit in operation, wherein the useful measurements {X′ₙ} are determined on the basis of the raw measurements {Xₘ},
further comprising:
determining a current distribution function F(x) associated with the useful measurements {X′ₙ},
determining an estimation \tilde{v} of the value v̅ of the operating physical quantity on the basis of the current distribution function F(x) and at least a portion of associations {Aₖ} saved in a memory, wherein each association Aₖ associates a model distribution function Fₖ(x) with a model value v*ₖ of the operating physical quantity.

10. A computer program downloadable from a communication network and/or saved on a computer-readable medium and/or executable by a processor, comprising instructions for executing the steps of the method as claimed in claim 9 when said program is executed on a computer.
